(19) United States
(12) Patent Application Publication
(10) Pub. No.: US 2020/0120798 A1
(43) Pub. Date: Apr. 16, 2020

(54) WIRING BOARD

(71) Applicant: SHINKO ELECTRIC INDUSTRIES CO., LTD., Nagano-shi (JP)

(72) Inventor: Yuji Yukiiri, Nagano-shi (JP)

(21) Appl. No.: 16/594,180

(22) Filed: Oct. 7, 2019

(30) Foreign Application Priority Data
Oct. 10, 2018 (JP) 2018-191375

(51) Int. Cl. H05K 1/11; H05K 3/40

(52) U.S. Cl. CPC H05K 1/115; H05K 2201/0959; H05K 3/4061

(57) ABSTRACT

A wiring board includes: a core substrate having a through hole; an electrically conductive layer provided on a wall face of the through hole; and a filling material with which the through hole is filled and that contacts the electrically conductive layer. The filling material includes: a main portion that includes a resin and an inorganic filler; and a buffering portion that contacts the main portion and the electrically conductive layer and that includes at least a resin. A ratio of the inorganic filler contained in the main portion is higher than a ratio of an inorganic filler contained in the buffering portion, or the buffering portion does not include any inorganic filler.

This application claims priority from Japanese Patent Applications No. 2018-191375, filed on Oct. 10, 2018, the entire contents of which are herein incorporated by reference.

### BACKGROUND

### 1. Technical Field

The present disclosure relates to a wiring board.

### 2. Background Art

Through holes (open holes) are formed in a core substrate included in a wiring board. A plating layer is formed on a wall face of each of the through holes, and a cavity inside the through hole is then filled with a filling material containing a resin and an inorganic filler. Wiring layers are provided on opposite upper and lower surfaces of the core substrate respectively, and electric continuity between the wiring layers can be attained by the plating layer formed thus on the wall face. In addition, since the cavity inside the through hole is filled with the filling material, the wiring layers can be also formed on an upper side and a lower side of the through hole of the core substrate. Therefore, the degree of freedom for drawing around a wiring pattern and wiring density can be improved (see e.g., JP-A-H6-275959, JP-A-2006-216714, and JP-A-2003-133672).

However, resistance may increase or disconnection may occur between the plating layer inside the through hole and the wiring layers on the core substrate. The increase of the resistance and the disconnection result in lowering of connection reliability.

### SUMMARY

Certain embodiments provide a wiring board.

The wiring board comprises:

a core substrate having a through hole;

an electrically conductive layer provided on a wall face of the through hole; and

a filling material with which the through hole is filled and that contacts the electrically conductive layer, wherein the filling material comprises:
a main portion that includes a resin and an inorganic filler; and
a buffering portion that contacts the main portion and the electrically conductive layer and that includes at least a resin.

A ratio of the inorganic filler contained in the main portion is higher than a ratio of an inorganic filler contained in the buffering portion, or the buffering portion does not include any inorganic filler.

### BRIEF DESCRIPTION OF DRAWINGS

FIG. 1 is a sectional view showing a structure of a wiring board according to a first embodiment;

FIG. 2 is a sectional view showing an electrically conductive layer, a filling material and first wiring layers;

FIGS. 3A to 3C are sectional views (Part 1) showing a manufacturing method of the wiring board according to the first embodiment;

FIGS. 4A to 4C are sectional views (Part 2) showing the manufacturing method of the wiring board according to the first embodiment;

FIGS. 5A to 5C are sectional views (Part 3) showing the manufacturing method of the wiring board according to the first embodiment;

FIGS. 6A to 6C are sectional views (Part 4) showing the manufacturing method of the wiring board according to the first embodiment;

FIGS. 7A to 7C are sectional views (Part 5) showing the manufacturing method of the wiring board according to the first embodiment;

FIGS. 8A and 8B are sectional views (Part 6) showing the manufacturing method of the wiring board according to the first embodiment;

FIGS. 9A to 9C are sectional views (Part 1) showing a manufacturing method of a wiring board according to a second embodiment;

FIGS. 10A to 10C are sectional views (Part 2) showing the manufacturing method of the wiring board according to the second embodiment; and

FIG. 11 is a sectional view showing a semiconductor package according to a third embodiment.

### DESCRIPTION OF EMBODIMENTS

The present inventor has performed keen examination to probe the cause of lowering of connection reliability in a wiring board according to the background art. As a result, it has been apparent that an inorganic filler contained in a filling material directly contacts a plating layer inside each through hole, and there is a place where peeling is apt to occur between the filling material and the plating layer. A resin contained in the filling material has an adhesive property to the plating layer inside the through hole but the inorganic filler substantially does not have any adhesive property. Therefore, when the inorganic filler directly contacts the plating layer inside the through hole, peeling is apt to occur between the filling material and the plating layer. In addition, it has been apparent that when such peeling occurs, the plating layer may be unable to restrain thermal deformation of the filling material. When the filling material is expanded due to the thermal deformation, the filling material tends to protrude outward in up and down directions of the core substrate from the through hole. Therefore, stress in a direction of pushing up from the filling material acts on each of the wiring layers positioned in the up and down directions of the filling material on the core substrate. Due to such stress, peeling occurs between the plating layer inside the through hole and the wiring layer on the core substrate, so that electric resistance increases or disconnection occurs between the plating layer inside the through hole and the wiring layer on the core substrate.

To solve this problem, the present inventor has performed keener examination in order to suppress the peeling between the filling material and the plating layer. As a result, the present inventor has arrived at the following embodiments. The embodiments will be described below specifically with reference to the accompanying drawings. Incidentally, when constituent elements having substantially the same functional configurations in the description of the present disclosure and the drawings are referred to by the same signs correspondingly and respectively, duplicate description thereof may be omitted.

### First Embodiment

A first embodiment will be described. The first embodiment relates to a wiring board.

[Structure of Wiring Board]

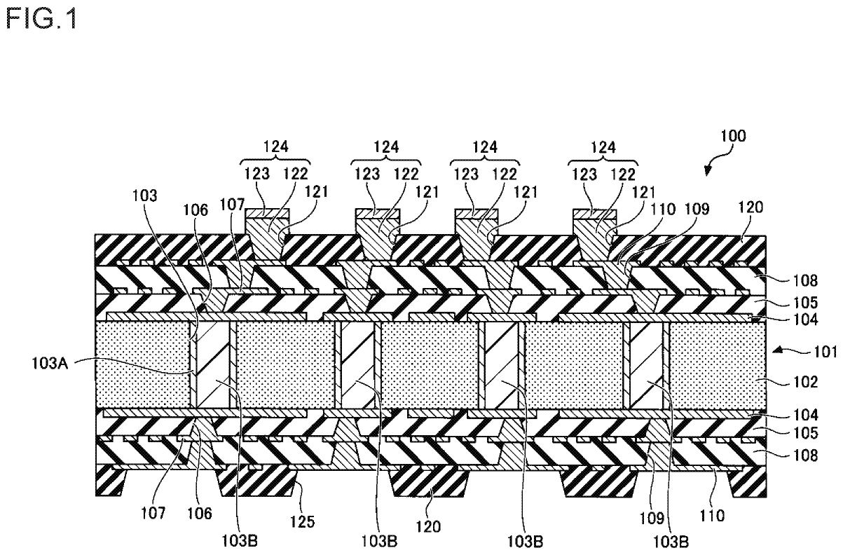

First, the structure of the wiring board will be described. FIG. 1 is a sectional view showing the structure of the wiring board according to the first embodiment.

As shown in FIG. 1, the wiring board 100 according to the first embodiment includes a core wiring substrate 101 as a support body. The core wiring substrate 101 includes a core substrate 102 formed of an insulating material such as a glass epoxy resin or a bismaleimide triazine resin. First wiring layers 104 made of copper etc. are formed on opposite surfaces of the core substrate 102 respectively. Through holes 103 are formed through the core substrate 102 in a thickness direction thereof. An electrically conductive layer 103A is provided on a wall face of each of the through holes 103. A filling material 103B is provided so that a portion inside the electrically conductive layer 103A in the through hole 103 is filled with the filling material 103B. The filling material 103B contains a resin. The first wiring layers 104 on the opposite sides of the core substrate 102 are connected to each other through the electrically conductive layer 103A. As will be described later, the electrically conductive layer 103A and the first wiring layers 104 share the same film.

First insulating films 105 are formed on the opposite sides of the core substrate 102 respectively. Via holes 106 are formed in the first insulating layers 105 to reach connection portions of the first wiring layers 104. Second wiring layers 107 are formed on the first insulating layers 105 respectively to be connected to the first wiring layers 104 respectively through via conductors inside the via holes 106. Further, second insulating layers 108 are formed on the first insulating layers 105 on the opposite sides of the core substrate 102 respectively. Via holes 109 are formed in the second insulating layers 108 to reach connection portions of the second wiring layers 107. Third wiring layers 110 are formed on the second insulating layers 108 respectively to be connected to the second wiring layers 107 respectively through via conductors inside the via holes 109.

Solder resist layers 120 are formed on the second insulating layers 108 on the opposite sides of the core substrate 102 respectively. Via holes 121 are formed in the solder resist layer 120 on the side of the core substrate 102 to be connected to a semiconductor chip so that the via holes 121 reach connection portions of the third wiring layer 110. Opening portions 125 are formed in the solder resist layer 120 on the opposite side of the core substrate 102 to thereby reach connection portions of the third wiring layer 110.

Connection terminals 124 are formed on the connection portions of the third wiring layer 110 on the side of the core substrate 102 to be connected to the semiconductor chip so that the connection terminals 124 protrude above the solder resist layer 120 through the via holes 121. Each of the connection terminals 124 includes a post 122, and a bump 123 laid on the post 122.

The melting point of the bump 123 is lower than the melting point of the post 122. For example, the post 122 contains copper (Cu) or nickel (Ni) or contains the both. The bump 123 contains tin (Sn) or solder. For example, the post 122 may have a copper plating film formed by an electroplating method, and a nickel plating film formed thereon. Examples of the solder include unleaded solder of a tin-silver (SnAg) based alloy, a tin-zinc (SnZn) based alloy, a tin-copper (SnCu) based alloy, etc. and leaded solder of a lead-tin (PbSn) based alloy.

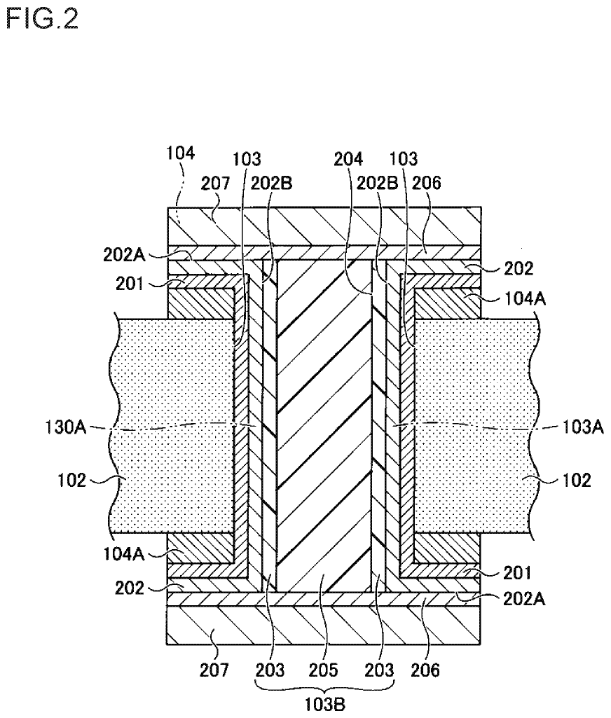

Here, details of the through hole 103, the electrically conductive layer 103A, the filling material 103B, and the first wiring layers 104 will be described. FIG. 2 is a sectional view showing the electrically conductive layer 103A, the filling material 103B and the first wiring layers 104.

As shown in FIG. 2, electrically conductive films 104A made of sheets of copper foil etc. are formed on the opposite surfaces of the core substrate 102 respectively. Each through hole 103 is formed in the core substrate 102 and the electrically conductive films 104A. An electroless copper plating film 201 is formed on surfaces of the electrically conductive films 104A and a wall face of the through hole 103. An electrolytic copper plating film 202 is formed on the electroless copper plating film 201. The electrolytic copper plating film 202 has faces 202A perpendicular to a thickness direction of the core substrate 102, and a face 202B parallel to the thickness direction of the core substrate 102. A first filling material 203 (an example of a buffering portion of a filling material) is formed on the face 202B of the electrolytic copper plating film 202 and annularly in plan view. That is, a hole 204 extending in the thickness direction of the core substrate 102 is present inside the first filling material 203. A second filling material 205 (an example of a main portion of the filling material) is provided in the hole 204. In addition, electroless copper plating films 206 are formed on the faces 202A of the electrolytic copper plating film 202, surfaces (end faces) of the first filling material 203, and surfaces of the second filling material 205 respectively. Further, electrolytic copper plating films 207 are formed on surfaces of the electroless copper plating films 206 respectively. The electrically conductive films 104A are, for example, the sheets of copper foil deposited on the surfaces of the core substrate 102.

Of an assembly of the electroless copper plating film 201 and the electrolytic copper plating film 202, a portion between the opposite surfaces of the core substrate 102 is included in the electrically conductive layer 103A. The first filling material 203 and the second filling material 205 are included in the filling material 103B. Of the assembly of the electroless copper plating film 201 and the electrolytic copper plating film 202, portions outside the opposite surfaces of the core substrate 202, the electrically conductive films 104A, the electroless copper plating films 206 and the electrolytic copper plating films 207 are included in the first wiring layers 104 respectively. The first filling material 203 is an example of the buffering portion. The second filling material 205 is an example of the main portion.

For example, the diameter of the through hole 103 is in a range of from 200 μm to 500 μm. In addition, the diameter of the hole 204 is smaller than the diameter of the through hole 103. For example, the diameter of the hole 204 is in the range of from 100 μm to 400 μm.

The first filling material 203 and the second filling material 205 contain a resin. The second filling material 205 further contains an inorganic filler. The first filling material 203 does not contain any inorganic filler, or contains an inorganic filler with a ratio lower than that of the second filler material 205.

For example, the second filling material 205 contains (i) a liquid epoxy resin, (ii) an epoxy monomer, (iii) a curing agent, and (iv) an inorganic filler.

For example, as (i) the liquid epoxy resin, an epoxy resin having flowability at normal temperature can be used. For example, an epoxy resin having viscosity of 20,000 mPa·s or less, particularly viscosity of 10,000 mPa·s or less, at room temperature is preferred. As (i) the liquid epoxy resin, a bisphenol A type epoxy resin, a bisphenol F type epoxy resin, etc. are enumerated.

For example, as (ii) the epoxy monomer, a monoepoxy monomer and polyepoxy monomers such as a diepoxy monomer and a triepoxy monomer are enumerated. (ii) The epoxy monomer is a constituent component of a matrix resin of the second filling material 205 and can serve as a diluent to adjust the viscosity of the second filling material 205.

For example, as (iii) the curing agent, an amine type curing agent is enumerated. As the amine type curing agent, for example, aliphatic (poly)amine etc. is enumerated. As the aliphatic (poly)amine, for example, chain aliphatic polyamine, cycloaliphatic amine, aliphatic amine, etc. are enumerated. (iii) The curing agent functions as a polymerization catalyst or a crosslinking agent of an epoxy group.

For example, (iv) the inorganic filler has a function of suppressing thermal expansion of the second filling material 205. For example, an inorganic filler having a particle size of 50 μm or less, particularly, a particle size of 0.01 μm to 25 μm is preferred. As the material of (iv) the inorganic filler, for example, barium sulfate, silica (including colloidal silica), aluminum hydroxide, magnesium hydroxide, alumina, titanium oxide, zirconium oxide, zirconium silicate, calcium carbonate, talc, mica, glass beads, clay, copper powder, feldspar powder, etc. are enumerated. Two or more kinds thereof may be used.

For example, the first filling material 203 contains (i) a liquid epoxy resin, (ii) an epoxy monomer, and (iii) a curing agent, but does not contain (iv) any inorganic filler.

In the first embodiment, the first filling material 203 does not contain any inorganic filler, or contains an inorganic filler with a ratio lower than that of the second filling material 205. Accordingly, the first filling material 203 can adhere to the electrolytic copper plating film 202 more firmly than the second filling material 205. In addition, the inorganic filler contained in the second filling material 205 contacts the first filling material 203 but hardly contacts the electrolytic copper plating film 202. Therefore, an excellent adhesive property between the filling material 103B and the electrically conductive layer 103A can be obtained so that connection reliability can be improved.

Further, even when the inorganic filler is contained with a high ratio in the second filler material 205, excellent connection reliability can be obtained. Accordingly, cure shrinkage of the filling material 103B can be suppressed so that a thermal expansion coefficient of the filling material 103B can be adjusted to the same degree as a thermal expansion coefficient of the core substrate 102. Accordingly, good stability can be secured in the wiring board 100.

Incidentally, it is preferable that the ratio of the inorganic filler contained in the first filling material 203 is lower. It is particularly preferable that the first filling material 203 does not contain any inorganic filler. This is for the purpose of obtaining a more excellent adhesive property to the electrolytic copper plating film 202.

[Manufacturing Method of Wiring Board]

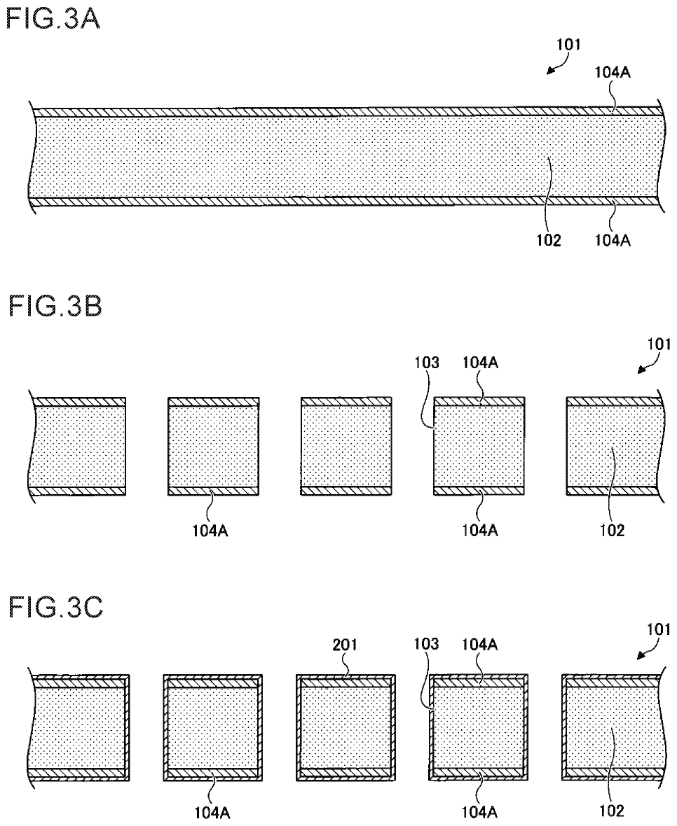

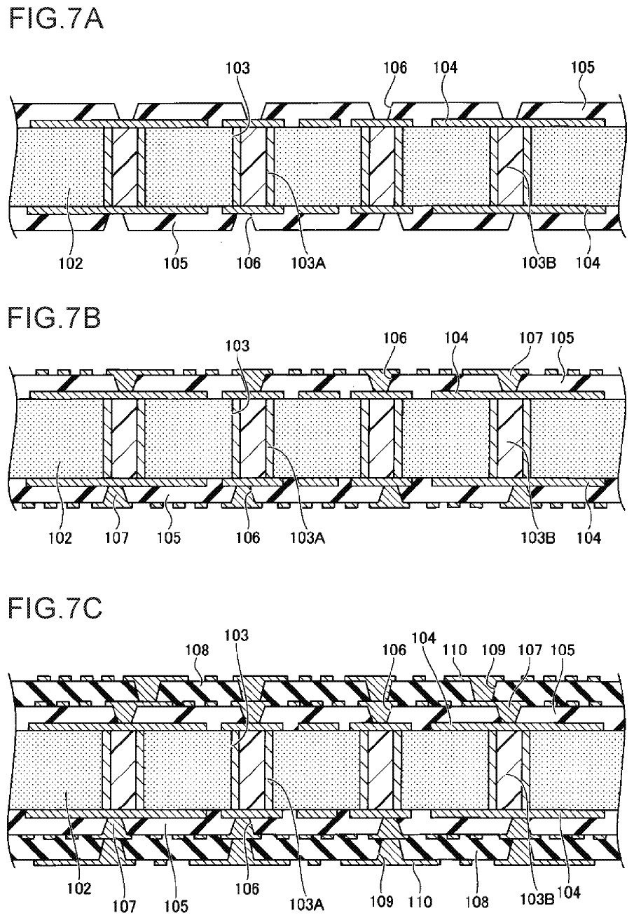

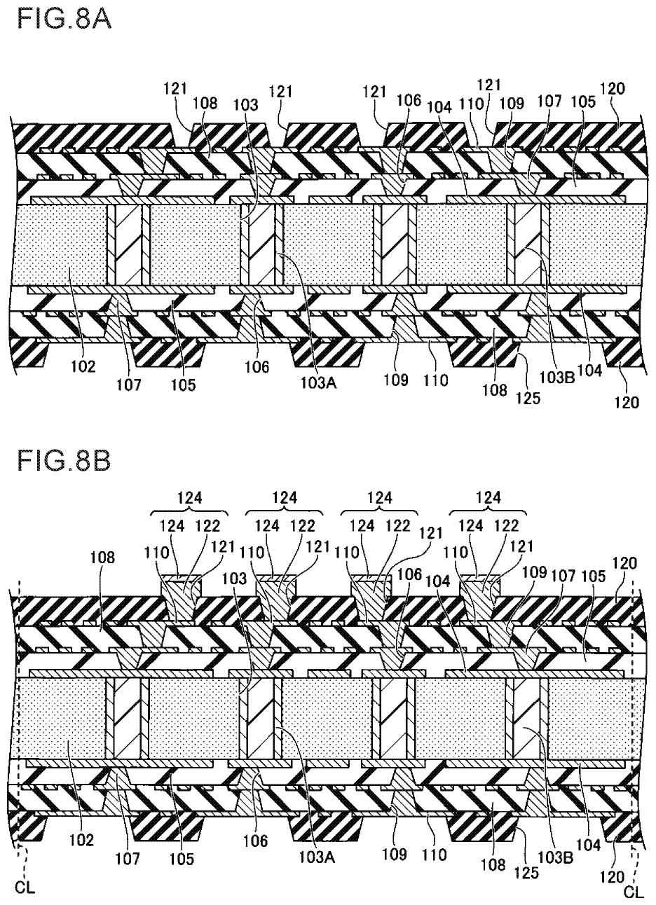

Next, a manufacturing method of the wiring board will be described. FIG. 3A to FIG. 8B are sectional views showing the manufacturing method of the wiring board according to the first embodiment. FIG. 3A to FIG. 6C mainly show steps about formation of the electrically conductive layers 103A, the filling materials 103B and the first wiring layers 104. FIG. 7A to FIG. 8B mainly show steps of forming the insulating layers, the wiring layers and the solder resist layers.

First, a core wiring substrate 101 provided with a core substrate 102 and electrically conductive films 104A is prepared, as shown in FIG. 3A. For example, the electrically conductive films 104A are sheets of copper foil. A large-sized substrate from which a plurality of wiring boards 100 can be obtained is used as the core wiring substrate 101. That is, the core wiring substrate 101 has a plurality of regions in each of which a structure body corresponding to the wiring board 100 can be formed.

Next, through holes 103 are formed to penetrate the core wiring substrate 101 in a thickness direction thereof, as shown in FIG. 3B. For example, the through holes 103 can be formed by machining using a drill or a laser, etc. For example, the diameter of each of the through holes 103 is set in a range of from 200 μm to 500 μm.

Then, desmear treatment is applied to surfaces of the electrically conductive films 104A and wall faces of the through holes 103. As shown in FIG. 3C, an electroless copper plating film 201 is formed on the surfaces of the electrically conductive films 104A and the wall faces of the through holes 103.

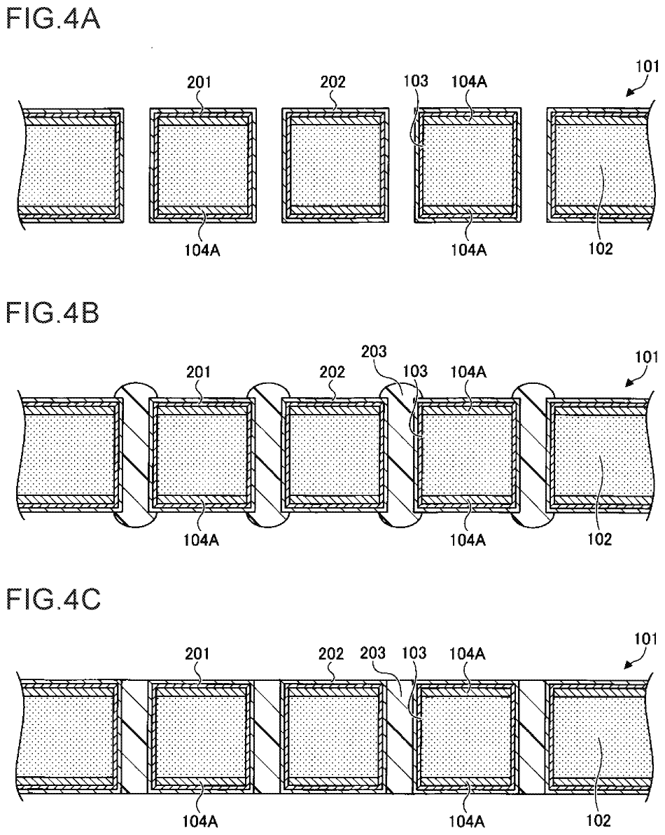

Successively, an electrolytic copper plating film 202 is formed on the electroless copper plating film 201 by an electroplating method using the electroless copper plating film 201 as a plating power feeding path, as shown in FIG. 4A.

Next, each of the through holes 103 is filled with a first filling material 203, as shown in FIG. 4B. For example, the first filling material 203 can be filled by a screen printing method. The first filling material 203 is provided on the electrolytic copper plating film 202 inside the through hole 103.

Then, the first filling material 203 is cured. As shown in FIG. 4C, of the first filling material 203, portions protruding outward from surfaces of the electrolytic copper plating film 202 are removed, so that surfaces of the first filling material 203 are made flush with the surfaces of the electrolytic copper plating film 202 respectively. When the first filling material 203 contains a thermosetting resin such as an epoxy resin, the first filling material 203 can be cured by heat treatment. For example, the protruding portions of the first filling material 203 can be removed by buff polishing or roll polishing.

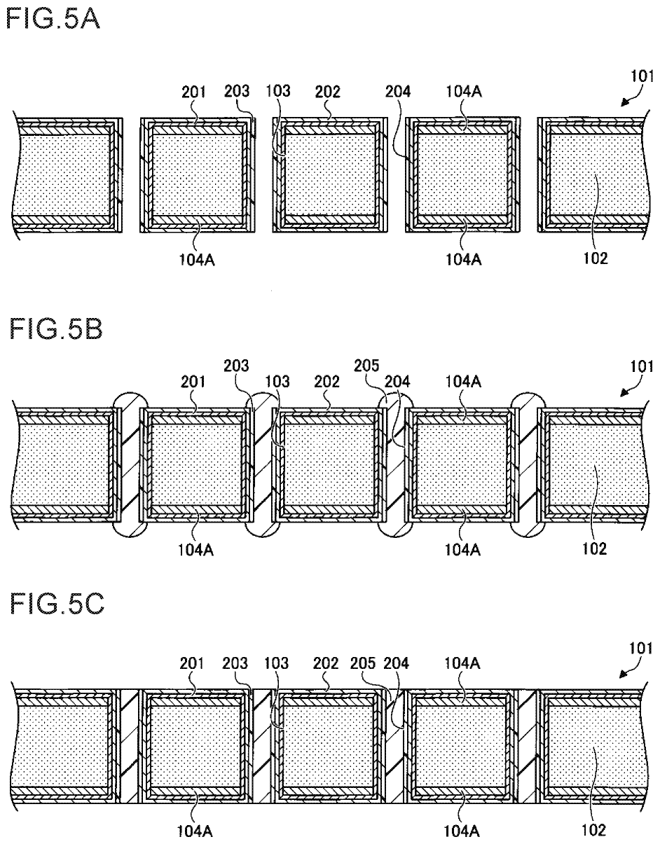

Successively, holes 204 are formed through the first filling materials 203 in the thickness direction thereof, as shown in FIG. 5A. The diameter of each of the holes 204 is smaller than the diameter of each of the through holes 103. For example, the hole 204 can be formed by machining using a drill or a laser, etc. For example, the diameter of the hole 204 is set in the range of from 100 μm to 400 μm.

Next, desmear treatment is applied to wall faces of the holes 204, and then, each of the holes 204 is filled with a second filling material 205, as shown in FIG. 5B. For example, the second filling material 205 can be filled by a screen printing method. The second filling material 205 is formed on the first filling material 203 inside the through hole 103. Incidentally, the desmear treatment may be applied to the wall face of the hole 204 as occasion demands.

Then, the second filling material 205 is cured. As shown in FIG. 5C, of the second filling material 205, portions protruding outward from the surfaces of the electrolytic copper plating film 202 are removed so that surfaces of the second filling material 205 are made flush with the surfaces of the electrolytic copper plating film 202 respectively. When the second filling material 205 contains a thermosetting resin such as an epoxy resin, the second filling material 205 can be cured by heat treatment. For example, the protruding portions of the second filling material 205 can be removed by buff polishing or roll polishing.

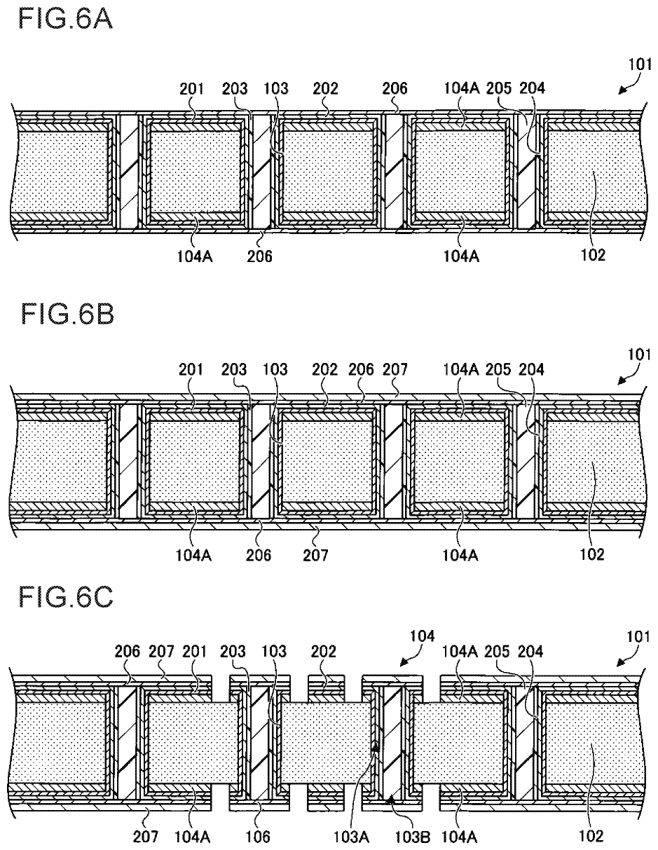

Successively, desmear treatment is applied to the surfaces of the electrolytic copper plating film 202, the surfaces (end faces) of the first filling material 203, and the surfaces of the second filling material 205. As shown in FIG. 6A, electroless copper plating films 206 are formed on the surfaces of the electrolytic copper plating film 202, the surfaces (end faces) of the first filling material 203, and the surfaces of the second filling material 205.

Next, electrolytic copper plating films 207 are formed on the electroless copper plating films 206 by an electroplating method using the electroless copper plating films 206 as plating power feeding paths, as shown in FIG. 6B.

Then, the electrolytic copper plating films 207, the electroless copper plating films 206, the electrolytic copper plating film 202, the electroless copper plating film 201 and the electrically conductive films 104A are machined, as shown in FIG. 6C. For example, the electrolytic copper plating films 207, the electroless copper plating films 206, the electrolytic copper plating film 202, the electroless copper plating film 201 and the electrically conductive films 104A can be machined by photolithography and etching. In this manner, an electrically conductive layer 103A, a filling material 103B, and first wiring layers 104 are formed.

As described above, of the assembly of the electroless copper plating film 201 and the electrolytic copper plating film 202, a portion between the opposite surfaces of the core substrate 102 are included in the electrically conductive layer 103A. The first filling material 203 and the second filling material 205 are included in the filling material 103B. Of the assembly of the electrically conductive films 104A, the electroless copper plating film 201 and the electrolytic copper plating film 202, portions outside the opposite surfaces of the core substrate 102, the electroless copper plating films 206 and the electrolytic copper plating films 207 are included in the first wiring layers 104 respectively.

After the electrically conductive layer 103A, the filling material 103B and the first wiring layers 104 are formed, uncured resin films are pasted on the opposite sides of the core substrate 102 respectively, and cured by heat treatment. As a result, first insulating layers 105 are formed. The first insulating layers 105 are formed from an insulating resin such as an epoxy resin or a polyimide resin. The first insulating layers 105 may be formed by applying a liquid resin. Then, the first insulating layers 105 on the opposite sides of the core substrate 102 are machined by a laser. As a result, via holes 106 are formed in the first insulating layers 105 to reach connection portions of the first wiring layers 104.

Successively, second wiring layers 107 are formed on the first insulating layers 105 on the opposite sides of the core substrate 102 to be connected to the first wiring layers 104 through via conductors inside the via holes 106, as shown in FIG. 7B.

The second wiring layers 107 can be formed by a semi-additive method. Here, the method for forming the second wiring layers 107 will be described in detail. First, seed layers (not shown) made of copper etc. are formed on the first insulating layers 105 and inner faces of the via holes 106 by an electroless plating method or a sputtering method. Next, plating resist layers (not shown) provided with opening portions in portions where the second wiring layers 107 should be formed are formed on the seed layers. Successively, metal plating layers made of copper etc. are formed in the opening portions of the plating resist layers by an electroplating method using the seed layers as plating power feeding paths. Then, the plating resist layers are removed. Next, the seed layers are removed by wet etching with the metal plating layers as masks. In this manner, the second wiring layers 107 each including the seed layer and the metal plating layer can be formed.

After the second wiring layers 107 are formed, second insulating layers 108 having via holes 109 provided on connection portions of the second wiring layers 107 are formed on the first insulating layers 105 on the opposite sides of the core substrate 102, as shown in FIG. 7C. The second insulating layers 108 can be formed by a method similar to or the same as that for the first insulating layers 105.

Further, third wiring layers 110 are formed on the second insulating layers 108 on the opposite sides of the core substrate 102 to be connected to the second wiring layers 107 through via conductors inside the via holes 109, also as shown in FIG. 7C. The third wiring layers 110 can be formed by a method similar to or the same as that for the second wiring layers 107.

Next, solder resist layers 120 are formed on the second insulating layers 108 on the opposite sides of the core substrate 102, as shown in FIG. 8A. Then, via holes 121 are formed in the solder resist layer 120 on the side of the core substrate 102 to be connected to a semiconductor chip so that the via holes 121 can reach connection portions of the corresponding third wiring layer 110. In addition, opening portions 125 are formed in the solder resist layer 120 on the opposite side of the core substrate 102 to reach connection portions of the corresponding third wiring layer 110.

The solder resist layers 120 are formed of an insulating resin such as a photosensitive epoxy resin or a photosensitive acrylic resin. Each of the solder resist layers 120 may be formed by pasting a resin film or applying a liquid resin. The via holes 121 and the opening portions 125 can be formed by exposure to light and development. An insulating resin such as a non-photosensitive epoxy resin or a non-photosensitive polyimide resin may be used for the solder resist layers 120. In this case, the via holes 121 and the opening portions 125 can be formed by laser machining or blast treatment.

Successively, as shown in FIG. 8B, connection terminals 124 are formed on the connection portions of the third wiring layer 110 on the side of the core substrate 102 to be connected to the semiconductor chip so that the connection terminals 124 protrude above the solder resist layer 120 through the via holes 121. Each of the connection terminals 124 includes a post 122 and a bump 123.

Next, structure bodies shown in FIG. 8B are cut by a slicer etc. along cut lines CL. Thus, the structure bodies each corresponding to a wiring board 100 are separated into individual pieces. Accordingly, a plurality of wiring boards 100 according to the first embodiment can be obtained from the large-sized core wiring substrate 101. In this manner, each of the wiring boards 100 according to the first embodiment as shown in FIG. 1 can be manufactured.

According to such a method, the wiring board 100 provided with the filling materials 103B with an excellent adhesive property to the electrically conductive layers 103A can be manufactured.

### Second Embodiment

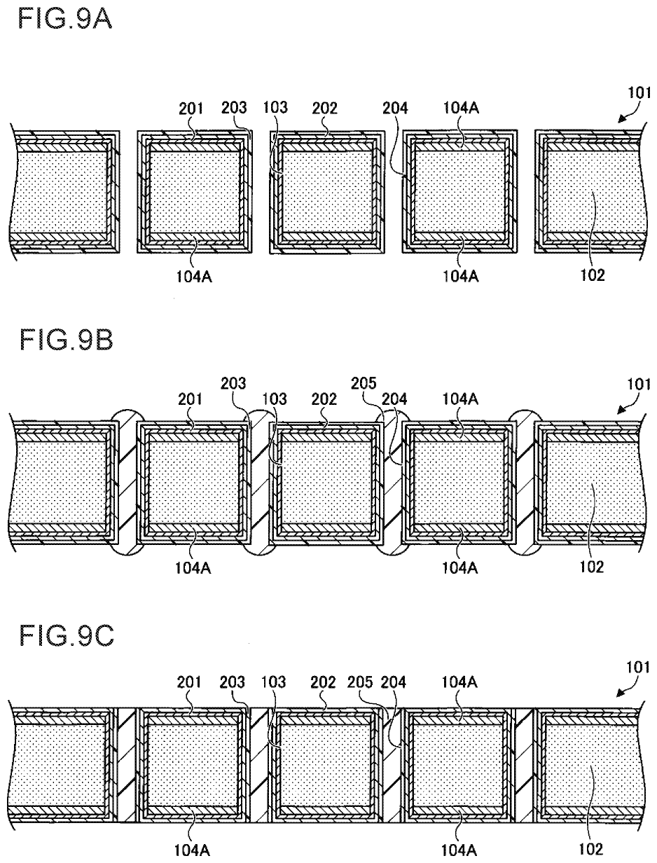

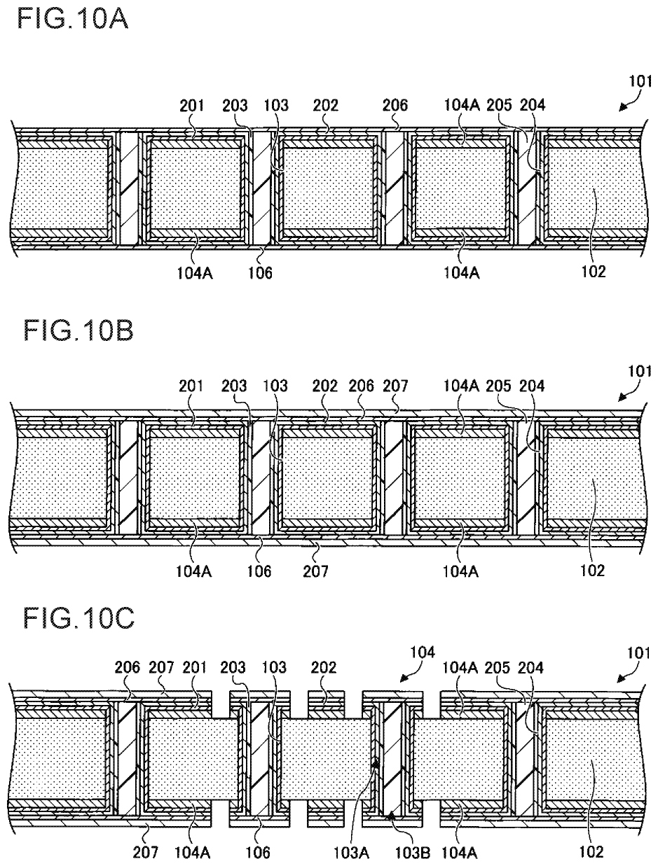

Next, a second embodiment will be described. The second embodiment differs in manufacturing method from the first embodiment. FIG. 9A to FIG. 10C are sectional views showing a manufacturing method of a wiring board according to the second embodiment.

In the second embodiment, first, steps up to formation of an electrolytic copper plating film 202 are performed in a manner similar to or the same as that in the first embodiment (see FIG. 4A). Next, a first filling material 203 is applied onto surfaces of the electrolytic copper plating film 202 by immersion treatment (dip treatment), as shown in FIG. 9A. Then, the first filling material 203 applied on the surfaces of the electrolytic copper plating film 202 is cured. As the first filling material 203, a material containing a resin with lower viscosity than the material used in the first embodiment is used. Each of the through holes 103 is temporarily filled with the first filling material 203 in the first embodiment (see FIGS. 4B and 4C), whereas spaces are left to form holes 204 inside through holes 103 in the second embodiment.

Then, desmear treatment is applied to wall faces of the holes 204, and each of the holes 204 is filled with a second filling material 205, as shown in FIG. 9B. For example, the second filling material 205 can be filled by a screen printing method. The second filling material 205 is formed on the first filling material 203 inside the through hole 103. Incidentally, the desmear treatment may be applied to the wall face of the hole 204 as occasion demands.

Successively, the second filling material 205 is cured, and, of the second filling material 205, portions protruding outward from the surfaces of the electrolytic copper plating film 202, and, of the first filling material 203, portions on the electrolytic copper plating film 202 in the thickness direction thereof are removed, as shown in FIG. 9C. In this manner, the surfaces of the electrolytic copper plating film 202, surfaces (end faces) of the first filling material 203, and surfaces of the second filling material 205 are made flush with one another respectively. When the second filling material 205 contains a thermosetting resin such as an epoxy resin, the second filling material 205 can be cured by heat treatment. For example, the protruding portions of the second filling material 205 and, of the first filling material 203, the portions on the electrolytic copper plating film 202 in the thickness direction thereof can be removed by buff polishing or roll polishing.

Next, desmear treatment is applied to the surfaces of the electrolytic copper plating film 202, the surfaces (end faces) of the first filling material 203, and the surfaces of the second filling material 205, and electroless copper plating films 206 are formed on the surfaces of the electrolytic copper plating film 202, the surfaces (end faces) of the first filling material 203, and the surfaces of the second filling material 205, as shown in FIG. 10A.

Then, electrolytic copper plating films 207 are formed on the electroless copper plating films 206 by an electroplating method using the electroless copper plating films 206 as plating power feeding paths, as shown in FIG. 10B.

Successively, the electrolytic copper plating films 207, the electroless copper plating films 206, the electrolytic copper plating film 202, the electroless copper plating film 201 and the electrically conductive films 104A are machined, as shown in FIG. 10C. For example, the electrolytic copper plating films 207, the electroless copper plating films 206, the electrolytic copper plating film 202, the electroless copper plating film 201 and the electrically conductive films 104A can be machined by photolithography and etching. In this manner, an electrically conductive layer 103A, a filling material 103B and first wiring layers 104 are formed.

Further, a step of forming first insulating layers 105 and following steps are performed in a manner similar to or the same as that in the first embodiment. Accordingly, wiring boards 100 are completed (FIG. 8B).

Also by such a method, the wiring boards 100 each provided with the filling materials 103B having an excellent adhesive property to the electrically conductive layers 103A can be manufactured.

### Third Embodiment

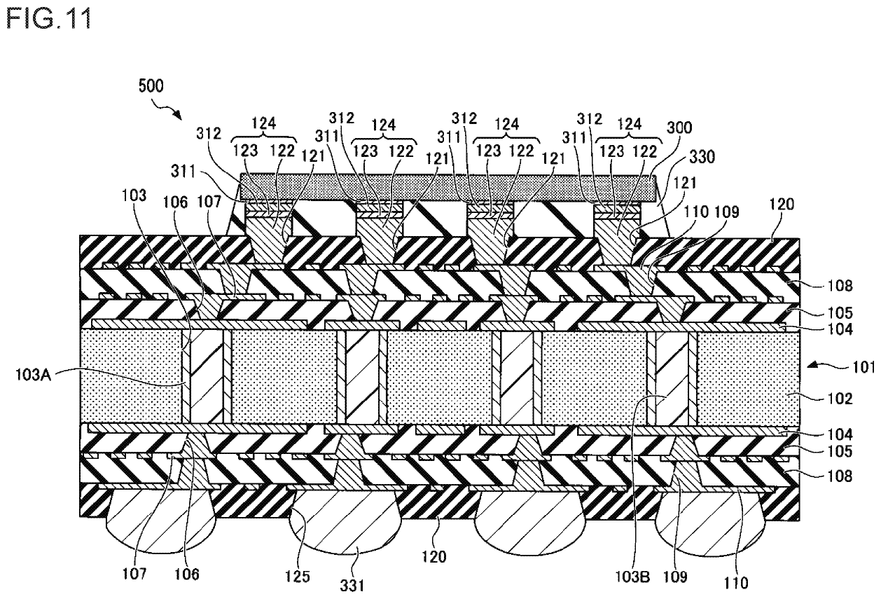

Next, a third embodiment will be described. The third embodiment relates to a semiconductor package. FIG. 11 is a sectional view showing the semiconductor package 500 according to the third embodiment.

As shown in FIG. 11, the semiconductor package 500 according to the third embodiment has a wiring board 100 according to the first embodiment, a semiconductor chip 300, bumps 312, an underfill resin 330, and external connection terminals 331.

The semiconductor chip 300 includes connection terminals 311 connected to connection terminals 124 through the bumps 312. The connection terminals 311 are, for example, electrode pads. For example, solder balls are used as the bumps 312. As the material of the solder balls, for example, unleaded solder of a tin-silver (SnAg) based alloy, a tin-zinc (SnZn) based alloy, a tin-copper (SnCu) based alloy, etc., and leaded solder of a tin-lead (PbSn) based alloy can be used in a manner similar to or the same as the bumps 123. A gap between the semiconductor chip 300 and a solder resist layer 120 of the wiring board 100 is filled with the underfill resin 330 such as an epoxy resin.

The external connection terminals 331 are provided on a third wiring layer 110 in an opposite surface of the wiring board 100 to the semiconductor chip 300. For example, solder balls similar to or the same as the bumps 312 can be used as the external connection terminals 331.

To manufacture such a semiconductor package 500, the wiring board 100 which has been separated into an individual piece is prepared, and the semiconductor chip 300 is flip-chip mounted on the wiring board 100 by use of the bumps 312. After the semiconductor chip 300 is mounted, the gap between the semiconductor chip 300 and the solder resist layer 120 is filled with the underfill resin 330. In addition, the external connection terminals 331 are formed on the third wiring layer 110.

In this manner, it is possible to manufacture the semiconductor package 500.

Preferred embodiments etc. have been described above in detail. However, the present disclosure is not limited to the aforementioned embodiments etc. but various modifications and substitutions can be added to the aforementioned embodiments etc. without departing from the scope described in claims.

Various aspects of the subject matter described herein are set out non-exhaustively in the following numbered clauses:

1) A method of manufacturing a wiring board, comprising:
forming a through hole in a core substrate;
forming an electrically conductive layer on a wall face of the through hole;
forming a buffering portion in the through hole so as to contact the electrically conductive layer, wherein the buffering portion includes at least a resin; and
forming a main portion in the through hole so as to contact the buffering portion; wherein the main portion includes a resin and an inorganic filler,
wherein a ratio of the inorganic filler contained in the main portion is higher than a ratio of an inorganic filler contained in the buffering portion, or the buffering portion does not include any inorganic filler.

2) The method according to clause (1), wherein
the forming the buffering portion comprises:
filling the through hole with a resin material; and
forming a second through hole to penetrate the resin material filled in the through hole, wherein a diameter of the second through hole is smaller than a diameter of the through hole.

3) The method according to clause (1), wherein
the forming the buffering portion comprises:
applying an uncured resin material onto the wall face of the through hole; and
curing the uncured resin material.

What is claimed is:

1. A wiring board comprising:
a core substrate having a through hole;
an electrically conductive layer provided on a wall face of the through hole, and
a filling material with which the through hole is filled and that contacts the electrically conductive layer, wherein the filling material comprises:
a main portion that includes a resin and an inorganic filler; and
a buffering portion that contacts the main portion and the electrically conductive layer and that includes at least a resin,
wherein a ratio of the inorganic filler contained in the main portion is higher than a ratio of an inorganic filler contained in the buffering portion, or the buffering portion does not include any inorganic filler.

2. The wiring board according to claim 1, wherein the buffering portion does not include any inorganic filler.

3. The wiring board according to claim 1, wherein
the buffering portion further includes an inorganic filler, and
the ratio of the inorganic filler contained in the main portion is higher than the ratio of the inorganic filler contained in the buffering portion.

4. The wiring board according to claim 1, wherein
the resin contained in the buffering portion and the resin contained in the main portion are the same type of resin.

5. The wiring board according to claim 4, wherein
the resin contained in the buffering portion and the resin contained in the main portion are an epoxy resin.

6. The wiring board according to claim 1, further comprising:
a first wiring layer formed on a first surface of the core substrate; and
a second wiring layer formed on a second surface of the core substrate, wherein the second surface is opposite to the first surface,
wherein the first wiring layer is electrically connected to the second wiring layer through the electrically conductive layer.
